(19) United States
(12) Patent Application Publication
(10) Pub. No.: US 2025/0030441 A1
(43) Pub. Date: Jan. 23, 2025

(54) FEC DECODING FOR CHANNELS WITH MEMORY

(71) Applicant: MaxLinear, Inc., Carlsbad, CA (US)

(72) Inventors: Rainer Strobel, München (DE); Gert Schedelbeck, München (DE); Vladimir Oksman, Morganville, NJ (US)

(73) Assignee: MaxLinear, Inc., Carlsbad, CA (US)

(21) Appl. No.: 18/778,848

(22) Filed: Jul. 19, 2024

Related U.S. Application Data
(60) Provisional application No. 63/514,362, filed on Jul. 19, 2023.

(51) Int. Cl. H03M 13/39; H03M 1/12; H03M 13/25

(52) U.S. Cl. CPC H03M 13/3927; H03M 1/1245; H03M 13/25

(57) ABSTRACT

An optical receiver includes a receiving component, a log-likelihood ratio component, and a forward error correction decoder. The receiving component may be configured to receive a data transmission of transmitted data and convert a portion of the data transmission into one or more digital samples. The log-likelihood ratio component may be configured to generate a log-likelihood ratio value using a set of the one or more digital samples. The forward error correction decoder may be configured to correct errors in in the log-likelihood ratio value and recover the transmitted data using the log-likelihood ratio value.

### CROSS REFERENCE TO RELATED APPLICATIONS

This U.S. Patent Application claims priority to U.S. Provisional Patent Application No. 63/514,362, titled “SOFT DECISION FEC DECODING FOR CHANNELS WITH MEMORY,” and filed on Jul. 19, 2023, the disclosure of which is hereby incorporated by reference in its entirety.

### TECHNICAL FIELD

This disclosure generally relates to network communications, and more specifically, to correcting bit errors in transmissions using forward error correction decoding when the transmission channel includes memory.

### BACKGROUND

Unless otherwise indicated herein, the materials described herein are not prior art to the claims in the present application and are not admitted to be prior art by inclusion in this section.

Some communication networks may be operable to support high bit rates as part of data transmissions. For example, passive optical networks (PONs) may include very high bit rates associated with transmitting data, such as 25 Gb/s (25G PON) or 50 Gb/s (50G PON). In some circumstances, a PON may include sensitive components (e.g., transmitters, receivers, etc.) that may contribute to transmissions including a very high bit rate, a low latency, and/or a low probability of errors in the transmitted data. Error correction may be implemented in the sensitive components, such that the PON (including the sensitive components) may reduce errors and/or the probability of errors and may contribute to the very high bit rate and/or low latency.

The subject matter claimed in the present disclosure is not limited to implementations that solve any disadvantages or that operate only in environments such as those described above. Rather, this background is only provided to illustrate one example technology area where some implementations described in the present disclosure may be practiced.

### SUMMARY

In an example embodiment, an optical receiver may include a receiving component, a log-likelihood ratio component, and a forward error correction decoder. The receiving component may be configured to receive a data transmission of transmitted data and convert a portion of the data transmission into one or more digital samples. The log-likelihood ratio component may be configured to generate a log-likelihood ratio value using a set of the one or more digital samples. The forward error correction decoder may be configured to correct errors in in the log-likelihood ratio value and recover the transmitted data using the log-likelihood ratio value.

In another embodiment, a device may include a receiving component and a decision algorithm input component. The receiving component may be configured to receive a data transmission and/or convert a portion of the data transmission into one or more digital samples. The decision algorithm input component may be configured to generate a log-likelihood ratio value using a set of the one or more digital samples.

In another embodiment, a method may include receiving a data transmission of transmitted data from a transmitting device. The method may also include converting a portion of the data transmission into one or more digital samples. The method may further include generating a log-likelihood ratio value using a set of the one or more digital samples. The method may also include correcting errors in the log-likelihood ratio value. The method may further include recovering the transmitted data using the log-likelihood ratio value.

The objects and advantages of the embodiments will be realized and achieved at least by the elements, features, and combinations particularly pointed out in the claims.

Both the foregoing general description and the following detailed description are given as examples and are explanatory and not restrictive of the invention, as claimed.

### DESCRIPTION OF DRAWINGS

Example implementations will be described and explained with additional specificity and detail using the accompanying drawings in which:

FIG. 1 illustrates a block diagram of an example system for forward error correction (FEC) decoding for channels with memory;

FIGS. 2A and 2B illustrate block diagrams of example components in a receiver for FEC decoding for channels with memory;

FIGS. 3A and 3B illustrate additional block diagrams of example components in a receiver for FEC decoding for channels with memory;

FIG. 4 illustrates a flowchart of an example method of FEC decoding for channels with memory;

FIG. 5 illustrates an example computing device; and

FIG. 6 illustrates equations that may be used in FEC decoding for channels with memory.

### DETAILED DESCRIPTION

In some circumstances, a 50 Gb/s passive optical network (50G PON) may operate having high bit rates, low latency, and/or extremely low error probability while using existing fiber deployments, such as fiber deployments associated with lower speed PONs, such as a 25 Gb/s (25G) PON. In such circumstances, the 50G PON may employ various forward error correction (FEC) techniques, which may include advanced FEC techniques. For example, low-density parity-check (LDPC) codes and/or other capacity achieving FEC codes may be used in a PON as an advanced FEC technique. In instances in which a PON uses various codes associated with advanced FEC techniques, such as LDPC codes, a FEC decoder may use a soft decision input, that may be in terms of a log-likelihood ratio (LLR), as described herein.

In some existing systems, PON hardware that may be configured to support a high bit rate (e.g., 50G PON) may include wideband optical components, which may come with an associated cost. In some instances, monetary costs associated with a high bit rate PON may be reduced by using older generation optical components (e.g., a receiver configured for 25G PON) which may support a narrower frequency band compared to a high bit rate receiver (e.g., a receiver configured for 50G PON). In some circumstances, using a narrowband receiver in a high bit rate PON may contribute to correlated errors to the signal in the PON, as received by the receiver. Alternatively, or additionally, correlated errors in a received signal may be due, in part, to chromatic dispersion in the PON and/or the components of the PON (e.g., the optical fibers carrying the signal). In some circumstances, employing digital equalization at the receiver (e.g., using a feed forward equalizer, a decision feedback equalizer, and/or other equalizers) may remove some of the correlated errors, but some correlated errors may persist. Applying an interleaving technique to packets included in the transmitted data may mitigate some performance losses due to the correlated errors.

In some prior approaches, a PON may use hard decision FEC codes (e.g., hard decision Reed-Solomon codes for 10G PON or hard decision LDPC codes for 25G PON) and may support lower transmission bit rates (e.g., relative to the 50G PON). Due to the hard decision FEC codes and/or correlated errors in a transmitted signal, the sensitivity of the receiver in the PON utilized in prior approaches may be unable to support a high bit rate. As a result, many receivers may be unfit for use in a high transmission bit rate PON as the receivers may use hard decision FEC codes that may be unable to support the reception of a data transmission having a high transmission bit rate.

Aspects of the present disclosure address these and other limitations by implementing a soft decision FEC decoder in a PON that may be operable to receive data transmissions having a high transmission bit rate. In at least some aspects of the present disclosure, a receiver (and/or components included in the receiver) in a PON may be operable to receive a data transmission and sample the data transmission into multiple digital samples. The receiver may use the multiple digital samples to obtain log-likelihood ratio values based on a mapping of the digital samples to values in a look-up table. The log-likelihood ratio values may be input into a soft decision FEC included in the receiver (where the receiver may be a soft decision receiver (e.g., analog-to-digital converter based)) which may improve performance of the reception of the data transmission by the receiver, including reducing correlated errors in the received data transmission. The receiver described in the present disclosure may be used in an optical network unit (ONU) receiver for high bit rate data transmissions and/or in an optical line termination (OLT) receiver. Alternatively, or additionally, the systems and methods described herein may be used in either upstream transmissions (e.g., as an OLT receiver) and/or downstream transmissions (e.g., as an ONU receiver).

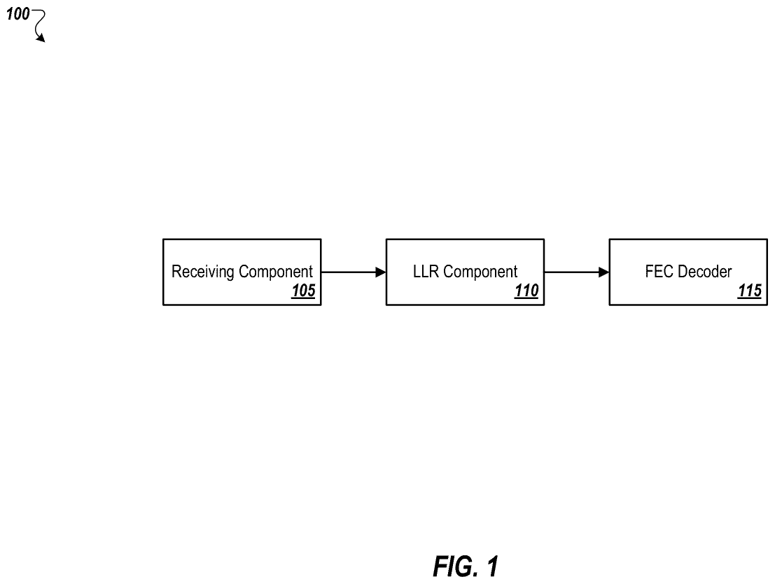

FIG. 1 illustrates a block diagram of an example system 100 for forward error correction (FEC) decoding for channels with memory, in accordance with at least one embodiment of the present disclosure. The system 100 may include a receiving component 105, a log-likelihood ratio component 110, and a FEC decoder 115.

The system 100 may be a receiver in a PON, such as an ONU receiver or an OLT receiver. The system 100 may be operable to obtain a data transmission from a transmitting device in the PON. In some instances, the data transmission may be some or all of transmitted data that may be transmitted from the transmitting device to the system 100. In some instances, the data transmission may be an analog signal.

In some instances, the receiving component 105 may be connected to the log-likelihood ratio component 110, which may be connected to the FEC decoder 115. In such arrangement, the receiving component 105 may be operable to generate one or more digital samples and transmit the one or more digital samples to the log-likelihood ratio component 110 and the log-likelihood ratio component 110 may be operable to generate a log-likelihood ratio value and transmit the log-likelihood ratio value to the FEC decoder 115, as described herein.

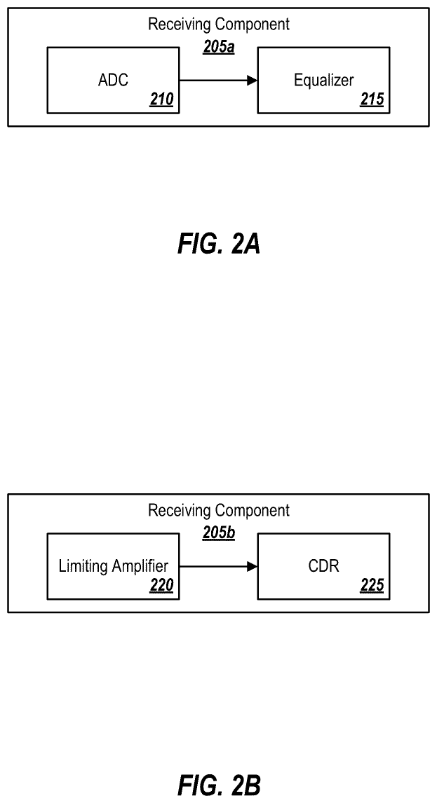

The receiving component 105 may be operable to obtain the data transmission and generate one or more digital samples from the data transmission by sampling the analog signal. The receiving component 105 may include different internal components based on the type of receiver in which the system 100 is configured to operate. For example, in instances in which the system 100 is a soft decision receiver, the receiving component 105 may include an analog-to-digital converter and/or an equalizer, as illustrated and discussed relative to FIG. 2A. In another example, in instances in which the system 100 is a hard decision receiver, the receiving component 105 may include a limiting amplifier and/or a clock-data-recovery element, as illustrated and discussed relative to FIG. 2B.

In these and other embodiments, the receiving component 105 may convert some or all of the received data transmission into one or more digital samples, and the digital samples may be transmitted to the log-likelihood ratio component 110. The log-likelihood ratio component 110 may be operable to use the one or more digital samples to generate a log-likelihood ratio value that may be input into the FEC decoder 115 for error correction, as described herein.

In some instances, the log-likelihood ratio value generated by the log-likelihood ratio component 110 may utilize more than one of the digital samples per log-likelihood ratio value. For example, multiple digital samples may be combined and/or collectively considered to generate the log-likelihood ratio value.

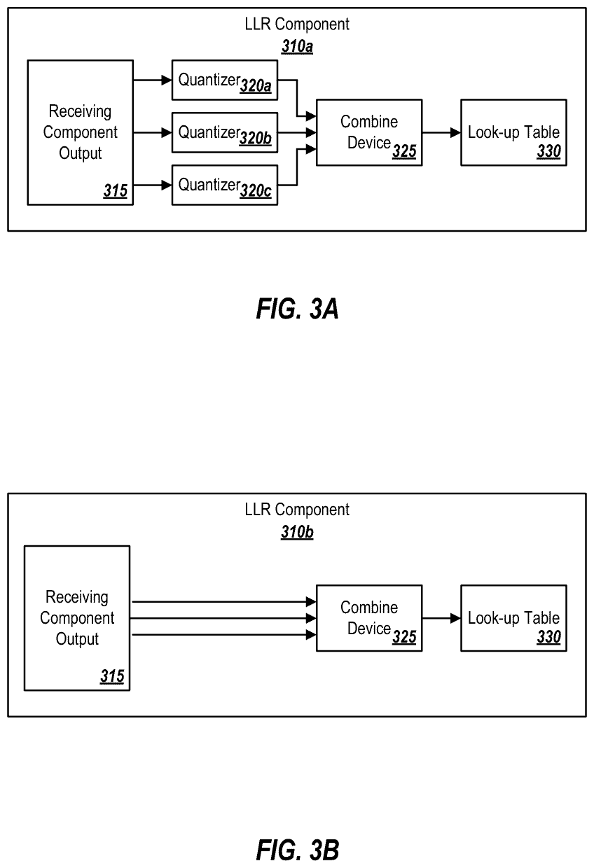

In instances in which the system 100 is a soft decision receiver, the log-likelihood ratio component 110 may include one or more quantize components and/or a combining block to combine the multiple digital samples, as illustrated and described relative to FIG. 3A. In instances in which the system 100 is a hard decision receiver, the log-likelihood ratio component 110 may include a combining component to combine the one or more digital samples obtained from the receiving component, as illustrated and described relative to FIG. 3B.

The log-likelihood ratio component 110 may be operable to use a set of the one or more digital samples to generate a log-likelihood ratio value. For example, the log-likelihood ratio component 110 may use a digital sample (e.g., that may occur at time t), a prior digital sample (e.g., that may occur at time t−1), and/or a subsequent digital sample (e.g., that may occur at time t+1) to obtain the log-likelihood ratio value. In the example, each of the digital samples may be included in the one or more digital samples obtained from the receiving component 105 and may collectively be a set of the one or more digital samples. Although the set of the one or more digital samples is described herein as including three digital samples, more or less of the one or more digital samples may be utilized to determine the log-likelihood ratio value.

In these and other embodiments, the log-likelihood ratio component 110 may be operable to generate the log-likelihood ratio value by mapping the set of the one or more digital samples to a look-up table and obtaining the log-likelihood ratio value from the look-up table. For example, the set of the one or more digital samples may be combined and the combined value may be mapped to the look-up table and based on the mapping, the log-likelihood ratio value may be obtained.

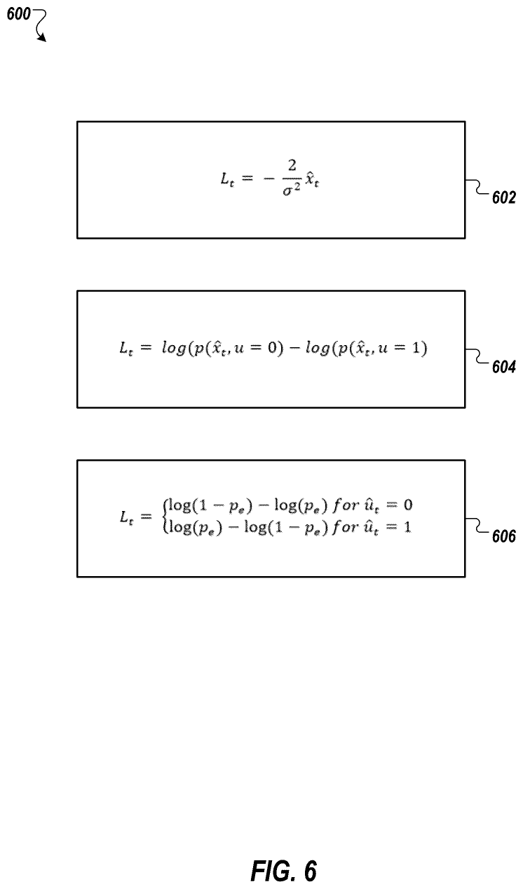

In instances in which the system 100 is a soft decision receiver, obtaining the log-likelihood ratio value via mapping to the look-up table may depend on a noise variance in the one or more digital samples obtained from the receiving component (e.g., that may be equalized digital samples, as described relative to FIG. 2A). For example, the log-likelihood ratio value (at a particular time t) in a soft decision receiver may be equal to a digital sample (at the particular time t) divided by the noise variance in the digital sample and the result therefrom multiplied by the constant negative two. The equation is illustrated as equation 602 in FIG. 6.

In instances in which a soft decision receiver is used, using a look-up table based log-likelihood ratio value calculation, a first probability value may represent a probability for receiving the digital sample at time t when a zero is transmitted and/or a second probability value may represent a probability for receiving the digital sample at time t when a one is transmitted. The first probability value and/or the second probability value may be obtained when the data transmission includes a known transmit sequence. In such instances, the log-likelihood ratio value may be obtained by subtracting the log of the second probability value from the log of the first probability value. The equation is illustrated as equation 604 in FIG. 6. The preceding equation may be an accurate log-likelihood ratio value calculation including scenarios in which the input signal (e.g., the one or more digital samples and/or the equalized digital samples) is not a Gaussian signal and/or the signal distribution of the input signal may not be known.

In instances in which the system 100 is a hard decision receiver, obtaining the log-likelihood ratio value via mapping to the look-up table may depend on a bit error probability associated with the one or more digital samples obtained from the receiving component (e.g., that may be a data bit sequence, as described relative to FIG. 2B). Determining the log-likelihood ratio value in a hard decision receiver may vary depending on the data bit. For example, the log-likelihood ratio value for a data bit equal to zero (at a particular time t) may be determined by the log of the bit error probability subtracted from the log of one minus the bit error probability. In another example, the log-likelihood ratio value for a data bit equal to one (at a particular time t) may be determined by the log of one minus the bit error probability subtracted from the log of the bit error probability. The equations for the different data bits in a hard decision receiver are illustrated as equation 606 in FIG. 6.

The FEC decoder 115 may be operable to correct errors in the log-likelihood ratio value obtained from the log-likelihood ratio component 110. In some instances, the output from the FEC decoder 115 may be the same or similar to the transmitted data obtained from a transmitting device (and received by the receiving component 105). The FEC decoder 115 may be operable to detect and/or remove errors, noise, and/or other corruptions that may be introduced to the transmitted data during the data transmission.

In some instances, the FEC decoder 115 may be a soft decision FEC decoder in that the FEC decoder 115 may implement a soft decision algorithm. Alternatively, or additionally, in some instances, the FEC decoder 115 may be a hard decision decoder, in that the FEC decoder 115 may implement a hard decision algorithm. The decision algorithm (e.g., the soft decision algorithm or the hard decision algorithm) associated with the FEC decoder 115 may be based on the receiving component 105 and/or the systems and devices included in the receiving component 105 (as described relative to FIGS. 2A and 2B). For example, in instances in which the receiving component 105 includes an analog-to-digital converter and an equalizer, the FEC decoder 115 may be a soft decision FEC decoder utilizing a soft decision algorithm. In another example, in instances in which the receiving component 105 includes a limiting amplifier and a clock-data-recovery element, the FEC decoder 115 may be a hard decision FEC decoder utilizing a hard decision algorithm.

In some instances, the log-likelihood ratio component 110 may be initialized prior to perform calculations to determine the log-likelihood values. In some embodiments, the initialization may include establishing a look-up table (see, for example, the look-up table 330 of FIGS. 3A and 3B) that may be used in conjunction with determining the log-likelihood ratio values. In these and other embodiments, the look-up table may be established by collecting signal amplitudes of the data transmission relative to transmitted bits for one or more symbols in the data transmission. In some embodiments, the initialization of the log-likelihood ratio component 110 may be based on whether the transmitted data is known or unknown.

In instances in which the transmitted data is known, the probability for the signal amplitudes associated with a first transmitted bit (e.g., bit 1) and the probability for the signal amplitudes associated with a second transmitted bit (e.g., bit 0) may be calculated with a number of occurrences of each combination of transmitted bit and received amplitude. In some instances, known bits (e.g., pilot bits) may be transmitted in a sequence. Alternatively, or additionally, the known bits may be transmitted intermixed with the transmitted data bits, where the transmitted data bits may be unknown by the system 100. The signal amplitudes around the known bits may be evaluated and/or a statistical determination of the correlation of the known bits (and/or bits adjacent to the known bits) may be determined by the system 100.

In some instances, a PON frame header may include a known sync pattern (e.g., Psync). Alternatively, or additionally, the PON frame header may include an overhead channel and/or a superframe counter. In some embodiments, the overhead channel and/or the superframe counter may not include fixed patterns. In some embodiments, the overhead channel may not change over time and/or the overhead channel may be repeated in each frame. Alternatively, or additionally, the superframe counter may be incremented in each frame. In such instances, the content of the overhead channel and/or the superframe counter may be predicted. In addition to the sync pattern, the overhead channel and/or the superframe counter may be used to initialize and/or train the log-likelihood ratio component 110 when the content of the overhead channel and/or the superframe counter are estimated in the initial frames.

In instances in which the transmit data is unknown (or does not include the known bits), an output of the FEC decoder 115 may be used as a reference signal. For example, in instances in which a FEC code word is decoded successfully, the FEC code word from the FEC decoder 115 may be used as a transmitted bit sequence as part of the transmitted data. Alternatively, or additionally, the signal amplitudes that correspond to the FEC code word may be stored and/or used to evaluate the transmitted data.

Modifications, additions, or omissions may be made to the system 100 without departing from the scope of the present disclosure. For example, in some instances, a de-interleaving component may be disposed between the log-likelihood ratio component 110 and the FEC decoder 115. In such instances, the de-interleaving component may be operable to remove error clusters that may be present in the log-likelihood ratio values from the log-likelihood ratio component 110. For example, correlated errors may be present in the log-likelihood ratio values and when input to the de-interleaving component, the correlated errors, or error clusters, may be removed from the log-likelihood ratio values. Subsequent to the error clusters being removed from the log-likelihood ratio values, the log-likelihood ratio values may be input to the FEC decoder for processing, as described herein.

In another example, the designations of different elements in the manner described is meant to help explain concepts described herein and is not limiting. Further, the system 100 may include any number of other elements or may be implemented within other systems or contexts than those described. For example, any of the components of FIG. 1 may be divided into additional or combined into fewer components.

FIGS. 2A and 2B illustrate block diagrams of an example receiving component 205a and an example receiving component 205b, respectively, that may be included in a receiver for FEC decoding for channels with memory, in accordance with at least one embodiment of the present disclosure. The receiving component 205a may include an analog-to-digital converter 210 and an equalizer 215. The receiving component 205b may include a limiting amplifier 220 and a clock-data-recovery element 225.

The receiving component 205a may be the same or similar as the receiving component 205 in FIG. 1 and may be operable to obtain a data transmission from a transmitting device, and generate one or more digital samples from the data transmission by sampling the analog signal transmitted by the transmitting device. The analog-to-digital converter 210 may obtain the data transmission (e.g., the analog signal) and may convert the data transmission into one or more digital samples. The equalizer 215 may process the one or more digital samples such that the one or more digital samples are equalized prior to being transmitted from the receiving component 205a. In some instances, the one or more digital samples (and/or the equalized digital samples) may be transmitted to a log-likelihood ratio component, such as the log-likelihood component 110 of FIG. 1, to determine a log-likelihood ratio value using the equalized digital samples. In these and other embodiments, the receiving component 205a may be the receiving component for a receiver that may implement soft decision FEC decoding, as described herein.

The receiving component 205b may be the same or similar as the receiving component 205 in FIG. 1 and may be operable to obtain a data transmission from a transmitting device, and generate one or more digital samples from the data transmission by sampling the analog signal transmitted by the transmitting device. The limiting amplifier 220 may obtain the data transmission (e.g., the analog signal) and may convert the data transmission into one or more digital samples and/or output the result to the clock-data-recovery element 225. The clock-data-recovery element 225 may be configured to translate the limiting amplifier output signal into a data bit sequence, which may also be referred to in the present disclosure as one or more digital samples. In some instances, the one or more digital samples (e.g., the data bit sequence) may be transmitted to a log-likelihood ratio component, such as the log-likelihood component 110 of FIG. 1, to determine a log-likelihood ratio value using the data bit sequence. In these and other embodiments, the receiving component 205b may be the receiving component for a receiver that may implement hard decision FEC decoding, as described herein. A receiver that may implement the receiving component 205b may also be referred to as a limiting-amplifier based receiver and/or a binary receiver.

Modifications, additions, or omissions may be made to the system 100 without departing from the scope of the present disclosure. For example, in some instances, the limiting amplifier 220 may be remote from the receiving component 205b and/or the limiting amplifier 220 may be remote from the receiver in which the receiving component 205b is implemented.

In another example, the designations of different elements in the manner described is meant to help explain concepts described herein and is not limiting. Further, the receiving component 205a or the receiving component 205b may include any number of other elements or may be implemented within other systems or contexts than those described. For example, any of the components of FIG. 2A or FIG. 2B may be divided into additional or combined into fewer components.

FIGS. 3A and 3B illustrate block diagrams of an example log-likelihood ratio component 310a and an example log-likelihood ratio component 310b, respectively, that may be included in a receiver for FEC decoding for channels with memory, in accordance with at least one embodiment of the present disclosure. The log-likelihood ratio component 310a may include a first quantizer 320a, a second quantizer 320b, a third quantizer 320c, referred to collectively as quantizers 320, a combine device 325, and a look-up table 330. The log-likelihood ratio component 310b may include the combine device 325, and the look-up table 330.

The log-likelihood ratio component 310a and the log-likelihood ratio component 310b may include at least some of the same or similar components. For example, the log-likelihood ratio component 310b may include the same or similar elements of the log-likelihood ratio component 310a, without including the quantizers 320. In some instances, the log-likelihood ratio component 310a may be used with a receiver that may implement soft decision FEC decoding, as described herein. In some instances, the log-likelihood ratio component 310b may be used with a receiver that may implement hard decision FEC decoding, as described herein.

In instances in which the receiving component includes an analog-to-digital converter and/or an equalizer (e.g., a soft decision receiver), the log-likelihood ratio component 310a and associated components, as illustrated in FIG. 3A, may be implemented. Alternatively, or additionally, in instances in which the receiving component includes a limiting amplifier and/or a clock-data recovery element (e.g., a hard decision receiver), the log-likelihood ratio component 310b and associated components, as illustrated in FIG. 3B, may be implemented.

The log-likelihood ratio component 310a may obtain a receiving component output 315, which may be the digital samples generated by the receiving component, such as the receiving component 105 of FIG. 1. Alternatively, or additionally, the receiving component output 315 may include multiple digital samples, such as a digital sample, a prior digital sample (relative to the digital sample), and a subsequent digital sample (relative to the digital sample). Each of the digital samples may be input to the quantizers 320, where the prior digital sample may be input to the first quantizer 320a, the digital sample input to the second quantizer 320b, and the subsequent digital sample input to the third quantizer 320c.

The quantizers 320 may be operable to reduce a resolution of at least the prior digital sample and/or the subsequent digital sample, which may contribute to reducing a size of the look-up table 330. For example, in some instances, a size of the look-up table 330 may grow exponentially as the number of digital samples and/or the time difference between the digital samples grows. The quantizers 320 may limit the number of digital samples and/or may control the time difference between the digital samples (e.g., may establish a threshold time difference for the prior digital sample and the subsequent digital sample relative to the digital sample), such that the size of the look-up table 330 may be controlled.

In instances in which the equalizer (e.g., the equalizer 215 of FIG. 2A) performs one or more operations prior to the log-likelihood ratio component 310a, the equalizer may impact statistical dependencies to the receiving component output 315, which may be used in the log-likelihood ratio component 310a. In some instances, a larger equalizer coefficient may cause issues related to stability and/or noise in the receiving component output 315. As such, in instances in which the equalizer output (e.g., the receiving component output 315) is subsequently provided to the log-likelihood ratio component 310a, one or more equalizer coefficients may be scaled down and/or saturated, which may cause an increased correlation between the errors in the receiving component output 315.

The output of the quantizers 320 may be combined by the combine device 325 and subsequently input into the look-up table 330. Based on the combined digital samples, a log-likelihood ratio value may be obtained from the look-up table 330, which log-likelihood ratio value may be input into a FEC decoder to obtain data that may be the same or similar as the transmitted data with errors and/or noise removed therefrom.

Similar to the log-likelihood ratio component 310a, the log-likelihood ratio component 310b may obtain a receiving component output 315, which may be the digital samples generated by the receiving component, such as the receiving component 105 of FIG. 1. Alternatively, or additionally, the receiving component output 315 may include multiple digital samples, such as a digital sample, a prior digital sample (relative to the digital sample), and a subsequent digital sample (relative to the digital sample). Unlike the log-likelihood ratio component 310a, the log-likelihood ratio component 310b may obtain the receiving component output 315 and input the digital samples to the combine device 325 without the use of the quantizers 320 in the log-likelihood ratio component 310a.

The combine device 325 may be operable to combine the receiving component output 315, which may include multiple digital samples (e.g., data bits from the data transmission) that may be consecutive data bits in the data transmission. In some instances, the combination of the multiple and/or consecutive bits in the data transmission may improve the quality of the log-likelihood ratio value obtained from the look-up table 330. Alternatively, or additionally, the log-likelihood ratio value may improve the performance of an associated FEC decoder (e.g., the FEC decoder 115 of FIG. 1), such as by reducing a number of iterations to be performed by low-density parity-check decoding.

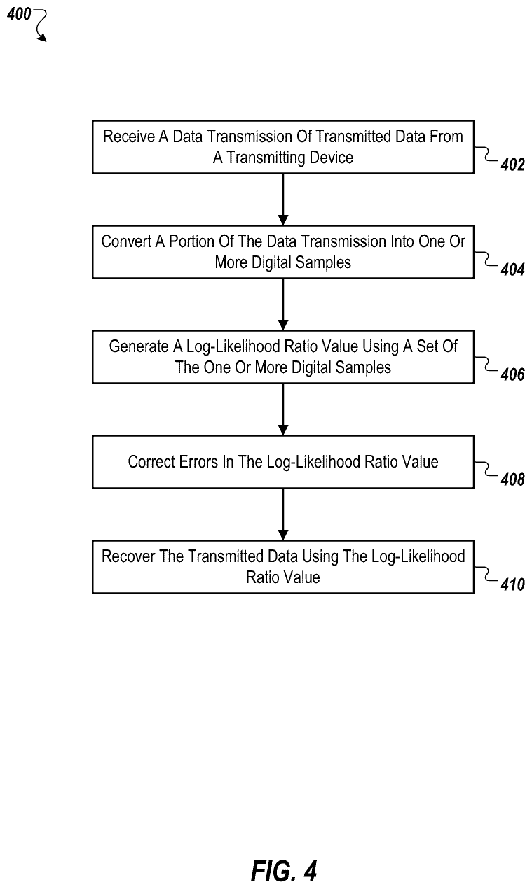

FIG. 4 illustrates a flowchart of an example method 400 of FEC decoding for channels with memory, in accordance with at least one embodiment of the present disclosure. The method 400 may be performed by processing logic that may include hardware (circuitry, dedicated logic, etc.), software (such as is run on a general purpose computer system or a dedicated machine), or a combination of both, which processing logic may be included in any computer system or device such as the system 100 of FIG. 1.

For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification may be capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

At block 402, a data transmission of transmitted data may be received from a transmitting device.

At block 404, a portion of the data transmission may be converted into one or more digital samples. In some instances, the set of the one or more digital samples may include a digital sample, a prior digital sample, and/or a subsequent digital sample.

At block 406, a log-likelihood ratio value may be generated using a set of the one or more digital samples. In some instances, the log-likelihood ratio value may be generated by mapping the set of the one or more digital samples to a look-up table.

At block 408, errors in the log-likelihood ratio value may be corrected. In some instances, a decision algorithm associated with the correcting errors in in the log-likelihood ratio value may be based on a receiving component configured to convert the portion of the data transmission into the one or more digital samples.

At block 410, the transmitted data may be recovered using the log-likelihood ratio value.

Modifications, additions, or omissions may be made to the method 400 without departing from the scope of the present disclosure. For example, the designations of different elements in the manner described is meant to help explain concepts described herein and is not limiting. Further, the method 400 may include any number of other elements or may be implemented within other systems or contexts than those described.

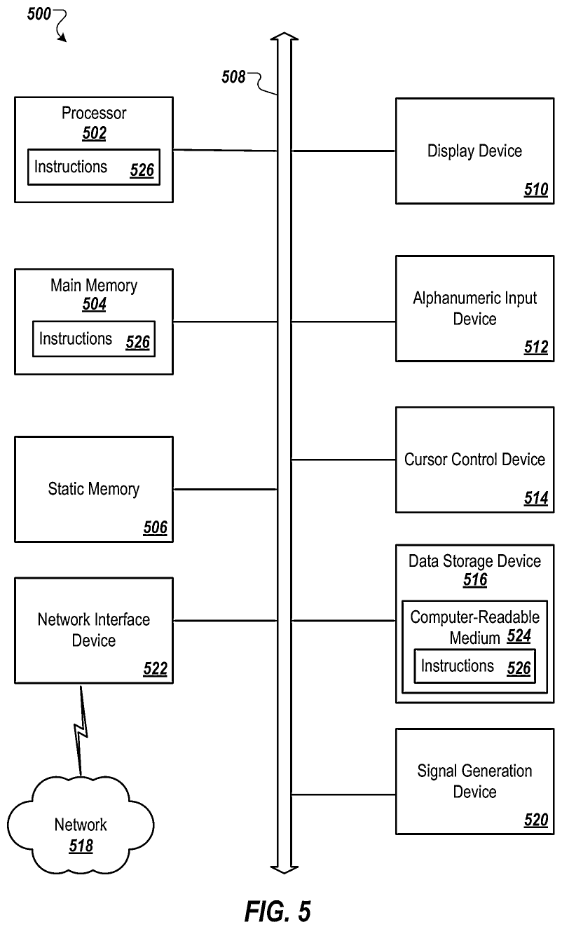

FIG. 5 illustrates an example computing device 500 within which a set of instructions, for causing the machine to perform any one or more of the methods discussed herein, may be executed. The computing device 500 may include a mobile phone, a smart phone, a netbook computer, a rackmount server, a router computer, a server computer, a personal computer, a mainframe computer, a laptop computer, a tablet computer, a desktop computer, or any computing device with at least one processor, etc., within which a set of instructions, for causing the machine to perform any one or more of the methods discussed herein, may be executed. In alternative implementations, the machine may be connected (e.g., networked) to other machines in a LAN, an intranet, an extranet, or the Internet. The machine may operate in the capacity of a server machine in client-server network environment. The machine may include a personal computer (PC), a set-top box (STB), a server, a network router, switch or bridge, an access point, a gateway, a wireless extender, or any machine capable of executing a set of instructions (sequential or otherwise) that specify actions to be taken by that machine. Further, while only a single machine is illustrated, the term “machine” may also include any collection of machines that individually or jointly execute a set (or multiple sets) of instructions to perform any one or more of the methods discussed herein.

The computing device 500 includes a processing device 502 (e.g., a processor), a main memory 504 (e.g., read-only memory (ROM), flash memory, dynamic random access memory (DRAM) such as synchronous DRAM (SDRAM)), a static memory 506 (e.g., flash memory, static random access memory (SRAM)) and a data storage device 516, which communicate with each other via a bus 508.

The processing device 502 represents one or more general-purpose processing devices such as a microprocessor, central processing unit, or the like. More particularly, the processing device 502 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 502 may also include one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein.

The computing device 500 may further include a network interface device 522 which may communicate with a network 518. The computing device 500 also may include a display device 510 (e.g., a liquid crystal display (LCD) or a cathode ray tube (CRT)), an alphanumeric input device 512 (e.g., a keyboard), a cursor control device 514 (e.g., a mouse) and a signal generation device 520 (e.g., a speaker). In at least one implementation, the display device 510, the alphanumeric input device 512, and the cursor control device 514 may be combined into a single component or device (e.g., an LCD touch screen).

The data storage device 516 may include a computer-readable storage medium 524 on which is stored one or more sets of instructions 526 embodying any one or more of the methods or functions described herein. The instructions 526 may also reside, completely or at least partially, within the main memory 504 and/or within the processing device 502 during execution thereof by the computing device 500, the main memory 504 and the processing device 502 also constituting computer-readable media. The instructions may further be transmitted or received over a network 518 via the network interface device 522.

While the computer-readable storage medium 524 is shown in an example implementation to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although implementations of the present disclosure have been described in detail, various changes, substitutions, and alterations could be made hereto without departing from the spirit and scope of the present disclosure.

What is claimed is:

1. An optical receiver, comprising:
a receiving component configured to receive a data transmission of transmitted data and convert a portion of the data transmission into one or more digital samples;
a log-likelihood ratio component configured to generate a log-likelihood ratio value using a set of the one or more digital samples; and
a forward error correction decoder configured to correct errors in in the log-likelihood ratio value and recover the transmitted data using the log-likelihood ratio value.

2. The optical receiver of claim 1, further comprising a de-interleaving component operable to obtain the log-likelihood ratio value, remove correlated errors in the log-likelihood ratio value to obtain a de-interleaved log-likelihood ratio value, and transmit the de-interleaved log-likelihood ratio value to the forward error correction decoder.

3. The optical receiver of claim 1, wherein the receiving component comprises an analog-to-digital converter and an equalizer to generate the one or more digital samples.

4. The optical receiver of claim 1, wherein the receiving component comprises a limiting amplifier and a clock-data-recovery element to generate the one or more digital samples.

5. The optical receiver of claim 1, wherein the set of the one or more digital samples comprises a digital sample, a prior digital sample, and a subsequent digital sample.

6. The optical receiver of claim 1, wherein the log-likelihood ratio value is generated by mapping the set of the one or more digital samples to a look-up table.

7. The optical receiver of claim 1, wherein a decision algorithm associated with the forward error correction decoder is based on the receiving component.

8. The optical receiver of claim 1, wherein the optical receiver is an optical network unit.

9. The optical receiver of claim 1, wherein the log-likelihood ratio component is initialized prior to generating the log-likelihood ratio value by collecting signal amplitudes of the data transmission relative to the transmitted data for one or more symbols in the data transmission.

10. A device, comprising:
a receiving component configured to receive a data transmission and convert a portion of the data transmission into one or more digital samples; and
a decision algorithm input component configured to generate a log-likelihood ratio value using a set of the one or more digital samples.

11. The device of claim 10, further comprising a de-interleaving component operable to obtain the log-likelihood ratio value, remove correlated errors in the log-likelihood ratio value to obtain a de-interleaved log-likelihood ratio value, and transmit the de-interleaved log-likelihood ratio value to a forward error correction decoder.

12. The device of claim 11, wherein a decision algorithm associated with the forward error correction decoder is based on the receiving component.

13. The device of claim 10, wherein the receiving component comprises an analog-to-digital converter and an equalizer to generate the one or more digital samples.

14. The device of claim 10, wherein the receiving component comprises a limiting amplifier and a clock-data-recovery element to generate the one or more digital samples.

15. The device of claim 10, wherein the set of the one or more digital samples comprises a digital sample, a prior digital sample, and a subsequent digital sample.

16. The device of claim 10, wherein the log-likelihood ratio value is generated by mapping the set of the one or more digital samples to a look-up table.

17. A method, comprising:
receiving a data transmission of transmitted data from a transmitting device;
converting a portion of the data transmission into one or more digital samples;
generating a log-likelihood ratio value using a set of the one or more digital samples;
correcting errors in the log-likelihood ratio value; and
recovering the transmitted data using the log-likelihood ratio value.

18. The method of claim 17, wherein the set of the one or more digital samples comprises a digital sample, a prior digital sample, and a subsequent digital sample.

19. The method of claim 17, wherein the log-likelihood ratio value is generated by mapping the set of the one or more digital samples to a look-up table.

20. The method of claim 17, wherein a decision algorithm associated with correcting errors in in the log-likelihood ratio value is based on a receiving component configured to convert the portion of the data transmission into the one or more digital samples.
